(19) United States
(12) Patent Application Publication
(10) Pub. No.: US 2009/0057866 A1
(43) Pub. Date: Mar. 5, 2009

(54) Microelectronic Package Having Second Level Interconnects Including Stud Bumps and Method of Forming Same

(76) Inventor: Linda L. W. Chow, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/845,427

(22) Filed: Aug. 27, 2007

(51) Int. Cl. H01L 23/52; H01L 21/00

(52) U.S. Cl. 257/690; 438/109; 257/E23.001; 257/E23.085

(57) ABSTRACT

A microelectronic package and a method of forming the package. The microelectronic package includes a first level package including: a package substrate having a die side and a carrier side a microelectronic die mounted on the package substrate at the die side thereof; and an array of first level interconnects etectrically coupling the die to the package substrate. The microelectronic package further includes: a carrier having a substrate side, the first level package being mounted on the carrier at the substrate side thereof; and an array of second level interconnects electrically coupling the first level package to the carrier, each of the second level interconnects including a stud bump made substantially of Au.

### FIELD

Embodiments of the present invention relate generally to the field of microelectronic fabrication, and, in particular to a method of providing second level interconnects between a package substrate including a die mounted thereon and a carrier such as the substrate of a motherboard or circuit board,

### BACKGROUND

Conventionally, second level interconnects according to the prior art are provided by way of solder balls. Second level interconnects include electrical interconnects provided between a package substrate having a die mounted thereon (hereinafter, a “first level package”), and a carrier such as the substrate of a circuit board. By “carrier,” what is thus meant herein is the next level substrate onto which the first level package is adapted to be mounted. Typically, the prior art uses a ball placement machine, such as, for example, a vacuum operated suction head, to place solder balls into registration with lands on a carrier. A solder resist layer may be disposed on the carrier, and the solder resist openings may be provided with flux prior to the solder ball placement process. The flux may be applied through a mask, or by way of a dip or spray process. The first level package and the carrier thereafter undergo a reflow process at temperatures up to about 260 degrees Celsius. After solder joint formation, the first level interconnects may be supplied with an underfill material, such as with an epoxy material.

Disadvantageously, using solder balls and solder reflow for second level interconnects can lead to open or cold joints or merged balls in the case of package substrate warpage, as shown in FIG. 1. In FIG. 1, a conventional microelectronic package 100 is shown including a first level package 101 comprising a package substrate 102 supporting a die 104 thereon The die 104 is shown as having been electrically and mechanically joined/bonded to the package substrate 102 by way of an array 106 of solder joints 108, and further by way of cured underfill material 110 as shown. An integrated heat spreader (IHS) lid 112 is further mounted onto package substrate 102 and thermally coupled to the die 104 by way of a thermal interface material (TIM) 114. Lid 112 is supported on the package substrate 102 by way of sealant 116. The first level package 101 is in turn supported on and electrically and mechanically bonded to a carrier 118, such as the substrate of a circuit board. Carrier 118 includes carrier lands 120 thereon adapted to allow an electrical connection of the carrier 118 to additional circuitry. In turn, package substrate 102 includes substrate lands 122 thereon adapted to allow an electrical connection of the first level package 201 to external circuitry. The lands 120 and/or 122 may include ENIG pads, for example. An array 124 of solidified solder pieces 126 is shown between the carrier lands 120 and the substrate lands 122. The solidified solder pieces 126 include some solder joints 128 making up the second level interconnects, and, in addition, a number of merged joints 130 and open/cold joints 132 between the package substrate 102 and the carrier 118.

Substrate warpage, as is welt know, may occur as a result of the reflow process to attach the die to the package substrate, because of differing coefficients of thermal expansion (CTE's) between the package substrate and the die mounted thereon. The use of underfill material may exacerbate the warpage of the package substrate. Where organic substrates are used, the warpage may be more pronounced as compared with non-organic substrate, because of the larger difference between the CTE's of an organic substrate and of the silicon used in the die. As seen in FIG. 1, a prior art microelectronic package may present merged joints and/or open/cold joints where solder is used for the second level interconnects, and this mainly as a result of the warpage of the substrate. The above results among others in poor yield and in poor device performance.

The prior art fails to provide a reliable, cost-effective package substrate structure and method that address the disadvantages of second level interconnects including solder joints obtained by way of solder ball placement.

### BRIEF DESCRIPTION OF THE DRAWINGS

FIG. 1 is a schematic side cross-sectional view of a prior art microelectronic package include solder joint second level interconnects;

FIGS. 2 and 3 are schematic side cross-sectional views microelectronic packages according to two respective embodiments;

FIG. 4 is a electron micrograph of a typical stud bump as may be used in embodiments;

FIG. 5 is a flow diagram showing stages in the fabrication of a microelectronic package according to an embodiment;

FIG. 6 is a top plan view of a microelectronic package according to one embodiment; and

FIG. 7 is a schematic view of an embodiment of a system incorporating a microelectronic package as shown in either of FIGS. 2 or 3.

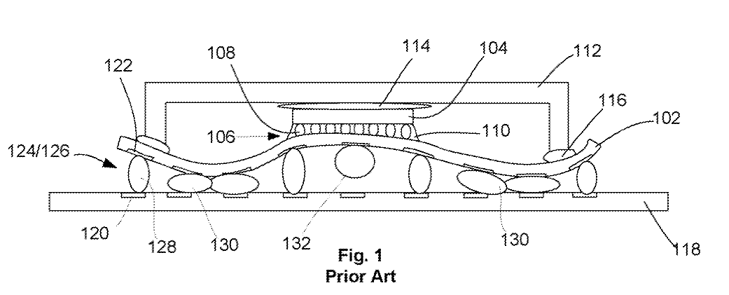

For simplicity and clarity of illustration, elements in the drawings have not necessarily been drawn to scale. For example the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic package including gold stud bumps as the second level interconnects, and a method of forming the same are disclosed. Reference is made to the accompanying drawings within which are shown, by way of illustrations specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to FIGS. X/Y showing an element A/B, what is meant is that FIG. X shows element A and FIG. Y shows element B.

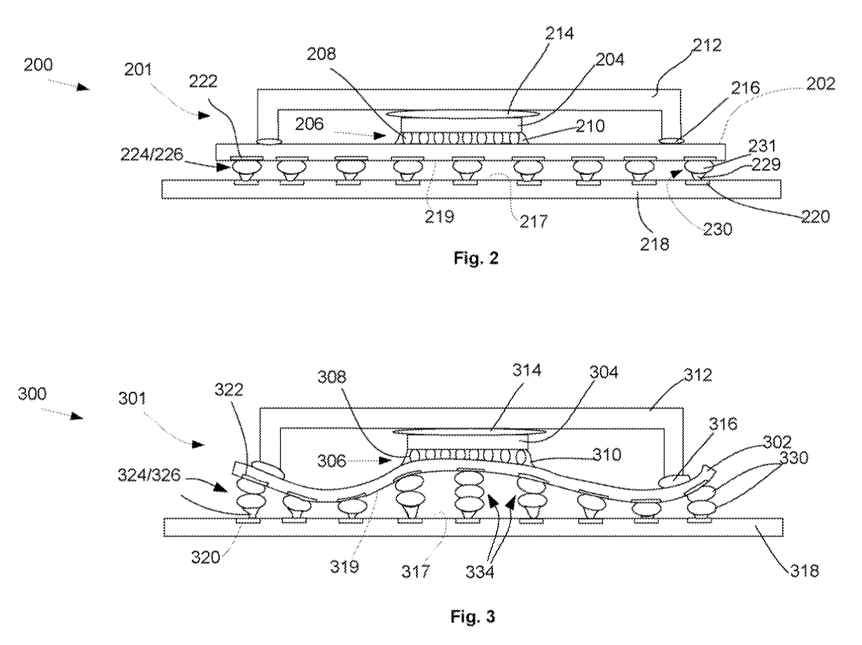

Aspects of this and other embodiments will be discussed herein with respect to FIGS. 2-7 below. The figures, however, should not be taken to be limiting, as it is intended for the purpose of explanation and understanding,

Referring to FIGS. 2/3 microelectronic package 200/300 is shown according to a first/second embodiment. In each of the embodiments, the package 200/300 may include a first level package 201/301 comprising a package substrate 202/302 supporting a die 204/304 thereon and having a die side and a carrier side. The die 204/304 may be mounted, that is, electrically and mechanically coupled to the package substrate 202/302 on the die side thereof, by way of an array 206/306 of first level interconnects including, for example, solder joints 208/308, and further by way of cured underfill material 210/310. Although a C4 solder connection is shown between die 204/304 and package substrate 202/302, it is noted that embodiments are not so limited, and include within their ambit any type of first level interconnection between die and package substrate, such as, for example, first level interconnects including wirebonds, conductive adhesives, or any other ones of well known die to substrate interconnects as would be within the knowledge of a skilled person. An integrated heat spreader (IHS) lid 212/312 may further be mounted onto package substrate 202/302 and thermally coupled to the die 204/304 by way of a thermal interface material (TIM) 214/314. Lid 212/312 is supported on the package substrate 202/302 by way of sealant 216/316, Additionally, although a lid IHS is shown in the embodiments of FIGS. 2 and 3, it is noted that embodiments are not so limited and include within their scope a package that does not include an IHS, and/or one that includes an IHS not necessary limited to a lid. The first level package 201/301 may in turn be mounted on, that is, electrically and mechanically coupled to, a carrier 2181318, such as the substrate of a circuit board. Carrier 218/318 may have a substrate side 217/317, and may include carrier lands 220/320 on the substrate side thereof adapted to allow an electrical connection of the carrier 218/318 to additional circuitry. In turn package substrate 202/302 may include substrate lands 222/322 on the carrier side 219/319 thereof adapted to allow an electrical connection of the first level package 201/301 to external circuitry. The lands 220/320 and/or 222/322 may include ENIG pads, for example, or any other type of land as would be within the knowledge of a skilled person. In general, the lands 220/320 and 222/322 may be made of a material that would provide a reliable connection of stud bumps 230/330 thereto, the configuration of the stud bumps being set forth later in the instant description. Although not shown, it is understood that a variety of components other than the die 2041304 may be placed on the package substrate or on the carrier as appropriate, including an On-Package-Voltage-Regulation device, or OPVR, an Integrated Semiconductor Voltage Regulator or ISVR., a Dynamic Random Access Memory or DRAM, or various other devices such as capacitors, inductor, resistors, and other first level packages, as would be within the knowledge of a skilled person.

An array 224/324 of second level interconnects 226/326 is shown between the carrier lands 220/320 and the substrate lands 222/322. The second level interconnects 2261326 include stud bumps 230/330, and, preferably, the stud bumps are made substantially of Au, that is, preferably, the stud bumps include at least 95% by weight Au. Preferably, the stud bumps are made of 99% by weight Au. By “stud bump,” what is meant in the context of the instant description is a bump or ball such as one that may be obtained by using a conventional wire bonding machine to achieve ball bonding, whether coined or not coined, as is well known in the art.

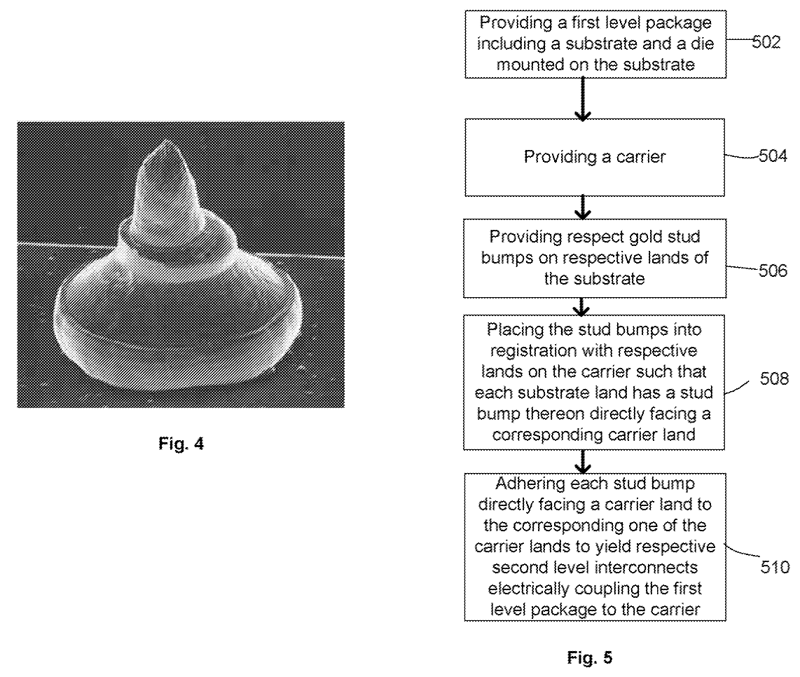

An exemplary view of a typical uncoined stud bump is shown in FIG. 4, which may be obtained as is well known, using a conventional wire bonding device to perform ball bonding. In ball bonding, the tip of the wire extending through a capillary of a wire bonding head is melted to form a sphere. The wire bonding tool then presses the sphere against the surface on which the sphere is resting, such as, in the case of embodiments, against either the substrate lands or the carrier lands. Pressing may be effected for example using mechanical force, heat, ultrasonic energy or a combination of the same to cause plastic deformation of the sphere and further atomic interdiffusion between the material of the sphere and the underlying metallization, such as, in the case of embodiments, between the gold material of the sphere and the metallization of the associated substrate land or carrier land, in this way forming a ball bond with the land. At this time, a wire clamp of the wire bonding tool may be closed to clamp off the wire, leaving a stud in the shape of the stud shown in FIG. 4. Typically, a largest diameter of a stud bump according to embodiments may be between about 20 microns and about 80 microns and more preferably about 50 microns. By “largest diameter,” what is meant in the context of embodiments is a diameter of a stud bump taken at its widest cross section. The stud bump may be further flattened, or “coined” after placement of the same by way of mechanical pressure in order to provide a flatter top surface and a more uniform bump height in this way pressing any wire tail into the ball. In FIG. 2/3 the stud bump of each of the interconnects 226/326 which directly faces a corresponding one of the carrier lands 218/318 is shown as including a wire tail portion 229/329 and a flattened ball portion 231/331, which may be formed as noted above.

Referring still to FIGS. 2 and 3, those figures differ in the fact that FIG. 2 shows a single layer of stud bumps 230 making up the second level interconnects, while FIG. 3 shows second level interconnects some of which include a plurality of stud bumps in the form of stacks. The structures within these figures will be described in further detail below.

Referring first to the embodiment of FIG. 2, the array 224 of stud bumps 230 includes a single layer of stud bumps 230, meaning that each of the second level interconnects 226 includes a single stud bump 230. Providing a single layer of stud bumps 230 may be beneficial in the case of relatively large pitches of the carrier lands, such as, for example, pitches in the order of hundreds of microns. In such a case, even in the case of substrate warpage, single stud bumps having a largest diameter in the order of tens of microns may be able to accommodate warpage of the package substrate. This is because a warpage of the package substrate with respect to the carrier, such as a warpage of substrate 202 with respect to carrier 218., may not be of a magnitude with respect to the large pitch of the carrier lands as to be appreciable (hence the substantially flat representation of substrate 202 in FIG. 2, although it is to be understood that substrate 202 may include warpage) require the use of stacked second level interconnects. In such a case, a pressing and further flattening of the single layer of stud bumps 230 during a mounting of the first level package 201 onto the carrier 218 may flatten each stud bump as a function of a warpage of the substrate, thus accommodating the same, while at the same time not compromising the integrity and reliability of the second level interconnects.

Referring next to FIG. 3, according to an embodiment, at least some of the second level interconnects 326 may include stacks 334 of stud bumps 330 as shown. As shown, the stacks 334 extend in a direction from the carrier side 319 of the package substrate 302 toward the substrate side 317 of the carrier 318. In the shown embodiment, the stacks are shown as having been provided to compensate for a warpage of the package substrate 302. By second level interconnects, such as stacks or studs, that “compensate for warpage,” what is meant in the context of the instant description are second level interconnects that, at each carrier land to substrate land second level connection, exhibit a height that ensures an electrical connection (without forming a open/cold joint) between the carrier and the warped package substrate, and that further do not exhibit a short between neighboring second level interconnects. In the embodiment of FIG. 3, the number of stud bumps 330 in each of the second level interconnects 326 is dependent on (e.g. proportional to) a distance between the carrier side 319 of package substrate 302 and the substrate side 317 of the carrier 318 at a location of the second level interconnect 326 being considered. In the particular embodiment shown in FIG. 3, for example, the maximum number of stud bumps for any of the interconnects is three, and corresponds to a location of the interconnect at a region of a maximum distance between the carrier side 319 of package substrate 302 and the substrate side 317 of carrier 318. Where an embodiment contemplates the provision of stacks of stud bumps as for example shown in FIG. 3, the stack may include: for example, anywhere from 1 stud bump up to about 15 stud bumps according to application needs. In general, the embodiment of FIG. 3 contemplates a provision of second level interconnects each of which has a height that allows an accommodation of a warpage of the package level substrate 302. To achieve the configuration of FIG. 3, embodiments contemplate for example a measurement of the warpage of the package substrate 302, such as, for instance, by way of using an ICOS WI-2200 Wafer Inspector available through the iCOS Vision Systems NV in Leuven, Belgium. Warpage measurement would then yield a determination of the profile of the warped substrate, in this way allowing a determination of the number of stud bumps necessary at each second level interconnect. The determination of the number of stud bumps would be a function of the warpage of the substrate, but also of the largest diameter contemplated for each stud bump, and of the height contemplated for each stud bump after pressure application to join the second level substrate to the carrier as will be explained in further detail below.

According to embodiments, a method of providing a microelectronic package may include, as shown in FIG. 5: at block 502 providing a first level package, such as first level package 201/301 of FIG. 2/3 above, and at block 504, providing a carrier such as carrier 218/318 of FIGS. 2/3 above. Such method may also include: at blocks 506-510, providing an array of second level interconnects electrically coupling the first level package to the carrier, such as second level interconnects 226/326 of FIG. 2/3. Specifically, at block 506, a method embodiment may include providing respective stud bumps on respective substrate lands. Providing the respective stud bumps could include providing a single layer of stud bumps, such as in the case of FIG. 2, or stacks of stud bumps, such as in the case of FIG. 3. The number of stud bumps in the case stacks could be determined as noted in the paragraph above, for example by way of measuring a warpage of the package substrate. Thereafter, at block 508, a method embodiment may include placing the respective stud bumps into registration with carrier lands of the carrier, such that each o the substrate lands includes a stud bump thereon which directly faces (that is, which is adapted to come into contact with) a corresponding one of the carrier lands. At block 510, a method embodiment may include adhering each stud bump that directly faces a carrier land to that carrier land to yield the second level interconnects. Adhering may include, for example, using a mechanical force or pressure, such as, for example, a pressure of about 500 mN per bump, or ultrasonic energy. A uniformly distributed force may be applied to the first level package and carrier by placing a weight on top of the first level package, for example. Ultrasonic energy, on the other hand, may be applied at the carrier land-stud bump interfaces by way of an ultrasonic transducer.

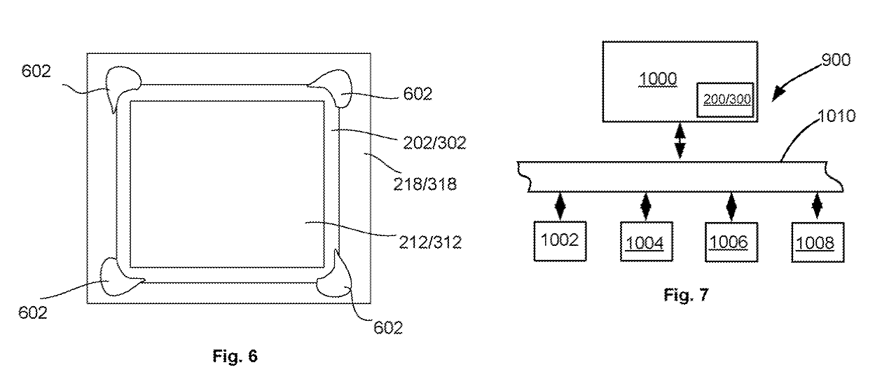

Referring next to FIG. 6, an embodiment is shown of a microelectronic package, where, to enhance the mechanical integrity of the connection between the first level package and the carrier, the first level package may be anchored by way of anchors 602. As shown in FIG. 6, anchors 602, such as, for example, mechanical clips, or double-sided epoxy or double-sided tape, may be used at the four corners of the substrate 202/302 to anchor the same down onto the carrier 218/318. Alternatively, the anchors 602 may include epoxy dispensed as underfill between the first level substrate and the carrier, or dispensed only at the package corners or peripheries.

Advantageously, embodiments provide a reliable cost-effective package substrate structure and method that address the disadvantages of second level interconnects including solder joints obtained by way of solder ball placement. In particular, embodiments allow a compensation of substrate warpage by second level interconnects including a single layer or stacks of stud bumps. Such a configuration eliminates the open/cold joints and merged solder joints often observed in prior art second level interconnects. Moreover, embodiments provide a simple and low-cost gold stud bumping process by: providing a method in which any ball wire-bonder can work, which is far less expensive than the use of ball placement machines; by dispensing with the use of ball placement macwinesh which typically take long tool conversion times (about 10 minutes); providing a method that allows flexibility by allowing the removal and addition of stud bumps to for an empirical compensation of warpage; by providing second level interconnects that are malleable, and that can thus be reworked even after mounting of the first level interconnect onto the carrier. Additionally, advantageously, embodiments provide the possibility to accommodate smaller pitches of the carrier lands as the technology progresses, for example, pitches in the order of tens of microns or in the order of the largest thickness of the stud bumps to be provided. Pitch changes may be easily accommodated by a simple programming of the wire bonder. Moreover, advantageously, embodiments provide a room temperature gold stud bumping method for second level interconnects, thus allowing the use of high performance transistors whose performance is preserved after bonding, and thus eliminating a source of further substrate warpage. Furthermore, embodiments advantageously provide second level interconnects having a simple IMC composition, since the knowledge of a goldgold system has been well established and is predictable. In this way second level interconnects may be obtained that offer an ultra-low electrical and thermal contact resistance as compared with leaded or lead-free joints of the prior art, in this way making the resulting package suitable for high power and high frequency applications. Moreover embodiments allow the provision of second level interconnects to advantageously dispense with the use of flux, or of solder resist layers on the carrier, thus simplifying the manufacture of microelectronic packages.

Referring to FIG. 7, there is illustrated one of many possible systems 900 in which embodiments of the present invention may be used. In one embodiment, the electronic assembly 1000 may include a microelectronic package, such as package 200 of FIG. 2 or package 300 of FIG. 3. Assembly 1000 may further include a microprocessor. In an alternate embodiment, the electronic assembly 1000 may include an application specific IC (ASIC), integrated circuits found in chipsets (e.g., graphics, sound, and control chipsets) may also be packaged in accordance with embodiments of this invention.

For the embodiment depicted by FIG. 7, the system 900 may also include a main memory 1002, a graphics processor 1004, a mass storage device 1006, and/or an input/output module 1008 coupled to each other by way of a bus 101, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server,

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package including:
a first level package including.
a package substrate having a die side and a carrier side;
a microelectronic die mounted on the package substrate at the die side thereof; and
an array of first level interconnects electrically coupling the die to the package substrate;
a carrier having a substrate side, the first level package being mounted on the carrier at the substrate side thereof; and
an array of second level interconnects electrically coupling the first level package to the carrier each of the second level interconnects including a stud bump

2. The package of claim 1, wherein the stud bump is made substantially of Au.

3. The package of claim 1, wherein at least some of the second level interconnects include a plurality of stud bumps.

4. The package of claim 3, wherein said plurality of stud bumps includes a stack of stud bumps extending a direction from the carrier side of the package substrate toward the substrate side of the carrier.

5. The package of claim 1, wherein the stack includes up to about 15 stud bumps.

6. The package of claim 4, wherein number of stud bumps of each of the second level interconnects is dependent on a distance between the carrier side of package substrate and the substrate side of the carrier at a location of said each of the second level interconnects.

7. The package of claim 1, wherein the second level interconnects have differing heights with respect to one another.

8. The package of claim 1, wherein each of the second level interconnects includes a single stud bump.

9. The package of claim 1, wherein the second level interconnects do not contain flux residuals.

10. The package of claim 1, wherein the stud bump has a largest diameter of about 50 microns.

11. The package of claim 1, wherein the substrate side of the carrier does not include a solder resist layer thereon.

12. A method of providing a microelectronic package, comprising:
providing a first level package including;
a package substrate having a die side and a carrier side, and substrate lands on the carrier side thereof;
a microelectronic die mounted on the package substrate at the die side thereof;
an array of first level interconnects electrically coupling the die to the package substrate;
providing a carrier having a substrate side and carrier lands on its substrate side;
providing an array of second level interconnects electrically coupling the first level package to the carrier, each of the second level interconnects including a stud bump, providing the array including:
providing respective stud bumps on respective substrate lands;
placing the respective stud bumps into registration with corresponding carrier lands such that each of the substrate lands includes a stud bump thereon directly facing a corresponding one of the carrier lands;
adhering each stud bump directly facing a corresponding one of the carrier lands to the corresponding one of the carrier lands to yield respective second level interconnects.

13. The method of claim 12, wherein the stud bump is made substantially of Au.

14. The package of claim 12, wherein providing respective stud bumps includes providing a stack of stud bumps on at least some of the respective substrate lands, the stack extending a direction from the carrier side of the package substrate toward the substrate side of the carrier.

15. The package of claim 14, wherein providing stud bumps further includes providing the stack on each of said at least some of the substrate lands such that the number of stud bumps in the stack is proportional to a distance between the carrier side of package substrate and the substrate side of the carrier at a location of said stack.
